(19) United States
(12) Patent Application Publication
(10) Pub. No.: US 2015/0223323 A1
(43) Pub. Date: Aug. 6, 2015

(54) Footprint for Prototyping High Frequency Printed Circuit Boards

(71) Applicant: Colin Patrick O'Flynn, Halifax (CA)

(72) Inventor: Colin Patrick O'Flynn, Halifax (CA)

(73) Assignee: Colin Patrick O'Flynn, Halifax (CA)

(21) Appl. No.: 14/173,106

(22) Filed: Feb. 5, 2014

(51) Int. Cl. H05K 1/02; H05K 1/11

(52) U.S. Cl. CPC H05K 1/0253; H05K 1/114

(57) ABSTRACT

A PCB footprint consisting of a plurality of pads, positioned such that many different electronic components can be mounted which would otherwise require a custom circuit board. One or more of the leads can be connected via a low-impedance path to a ground plane, making a suitable platform for prototyping high-frequency designs.

### RELATED APPLICATIONS

U.S. Pat. No. 5,683,788

U.S. Pat. No. 5,805,428

U.S. Pat. No. 6,405,920

U.S. Pat. No. 5,266,747

U.S. Patent Application 2012/0236,516

### STATEMENT OF FEDERALLY SPONSORED RESEARCH

Not Applicable

### NAMES OF PARTIES TO A JOINT RESEARCH AGREEMENT

Not Applicable

### SEQUENCE LISTING

Not Applicable

### BACKGROUND OF THE INVENTION

Modern electronic components are typically mounted on Printed Circuit Boards (PCB). A PCB is typically made by etching a desired pattern into a copper layer, where multiple such copper layers may be sandwiched together using a non-conductive substrate.

To mount a component to a PCB, a pattern which matches the ‘footprint’ of the device must be etched into that PCB. Each ‘lead’ on the device correct matches a ‘pad’ on the PCB, and can be joined by soldering the component to the PCB.

When prototyping designs, it is desirable to have a method of testing a part or design without requiring a new PCB to be designed and etched. This is difficult as electronic components come in a variety of package sizes. Previous multi-function footprints were often limited to 2 or 3-terminal devices, such as U.S. Pat. No. 5,683,788 or U.S. Pat. No 5,805,428. Such patterns are also unsuitable for high-frequency components, as no consideration has been given to the requirement of impedance matching and low-impedance ground paths.

### SUMMARY OF THE INVENTION

A footprint which can be used with most popular packages of high-frequency component. Packages that can be mounted include SOT-23, SOT-363, SOT-343, SOT-89, 4-pin round plastic, SOIC-8, ceramic filter package, and many custom devices. The careful mounting of a ground connection allows a low-impedance ground path which works with most of the packages.

The above footprint is implemented in a circuit board which contains additional features for prototyping, such as the ability to chain multiple PCBs together without connectors. Many variations of the design of this footprint or PCB are possible to those knowledgeable in the art.

### BRIEF DESCRIPTION OF THE DRAWINGS

FIG. 1 is a view of an implementation of the footprint

FIG. 2 is a view of an implementation of the footprint with a low-impedance ground path on the central pad

FIG. 3 is a view of the prototyping PCB using the footprint from FIG. 1.

FIG. 4 is a view of the prototyping PCB using the footprint from FIG. 2.

FIG. 5A is a view of the SOT-23-5 device mounted

FIG. 5B is a view of the SOT-363 device mounted

FIG. 5C is a view of the SOT-343 device mounted with three transmission lines and a ground pad

FIG. 5D is a view of the SOT-89 device mounted with a ground pad

FIG. 5E is a view of the SOIC-8 device mounted

FIG. 5F is a view of the ceramic filter device mounted

FIG. 6 is a view of interconnected prototyping PCBs

### DETAILED DESCRIPTION

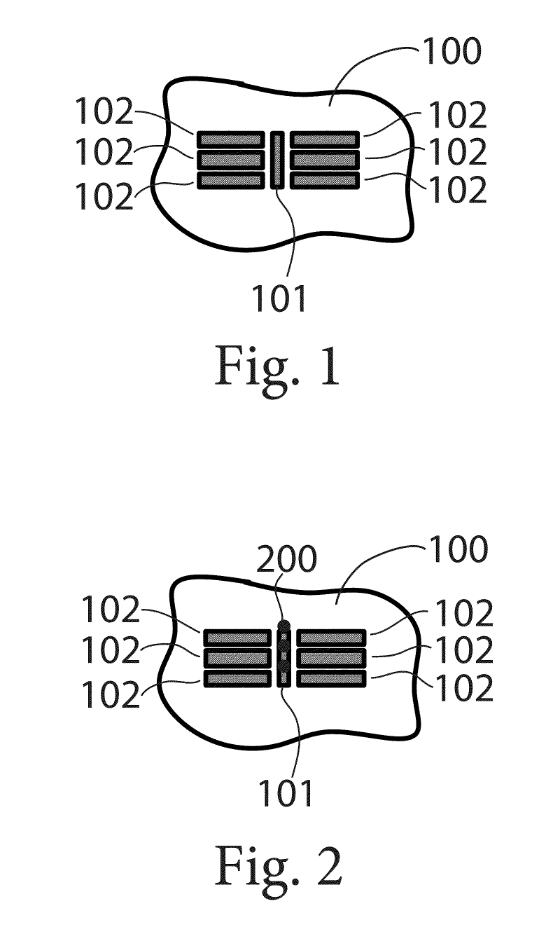

FIG. 1 and FIG. 2 show two possible embodiments of the footprint. The footprint is mounted on a substrate 100. The plurality of copper pads 101 and 102 can be used for component mounting. When a specific component is mounted a plurality of pads may be used, not all pads are used for every component type. The central pad 101 may optionally have via(s) 200 connecting to a ground plane under the central footprint.

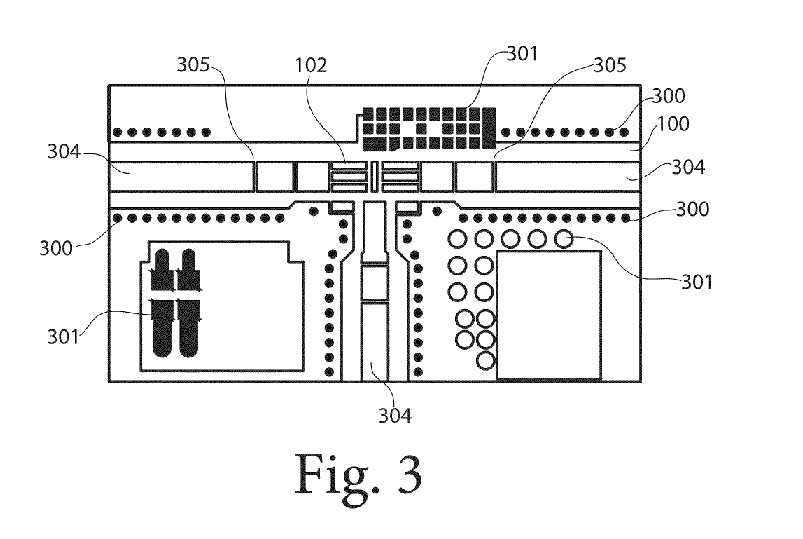

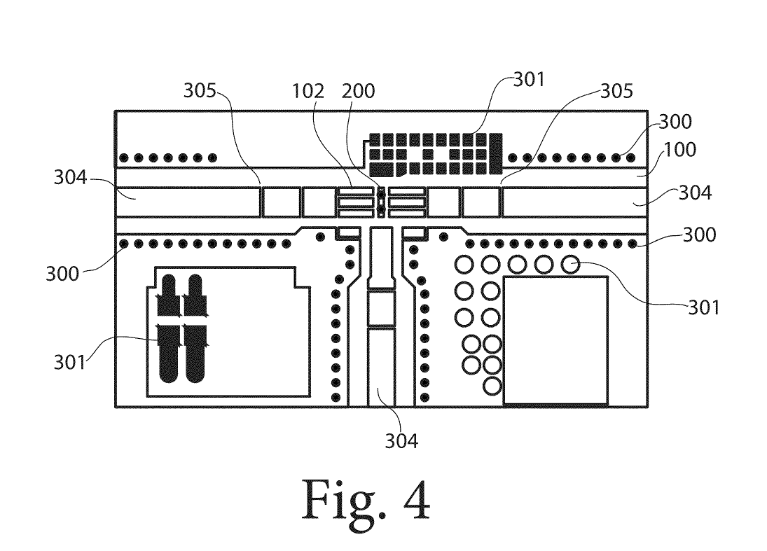

FIG. 3 and FIG. 4 show a prototyping PCB using the footprint, where FIG. 3 has a footprint as in FIG. 1 and FIG. 4 has a footprint as in FIG. 2. The board is etched onto a substrate 100, and portions of the board may be connected to a ground plane using vias 300. Additional pads such 301 are used for prototyping through hole and surface mount parts. The transmission lines 304 extend to the edge of the board. Slots 305 are made in the transmission line to allow placing of components such as resistors across the divide. The transmission line can connect to the plurality of fingers 102 of the central footprint.

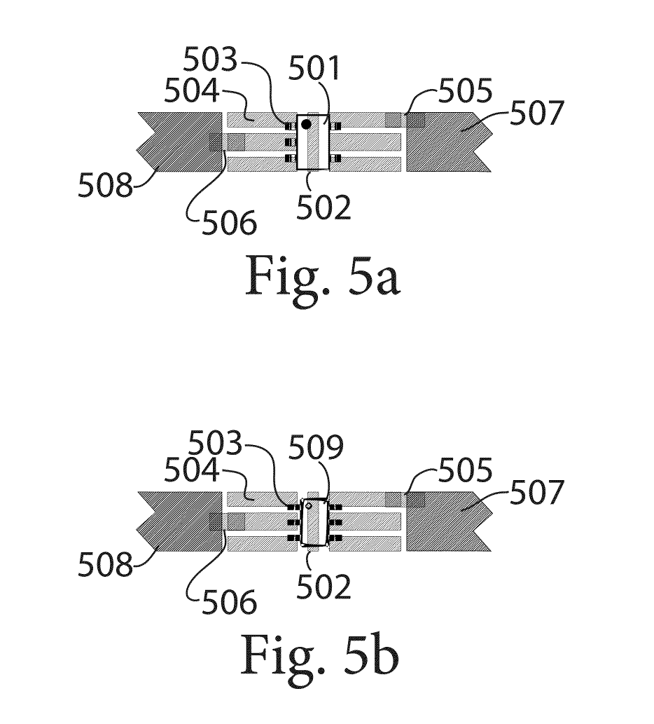

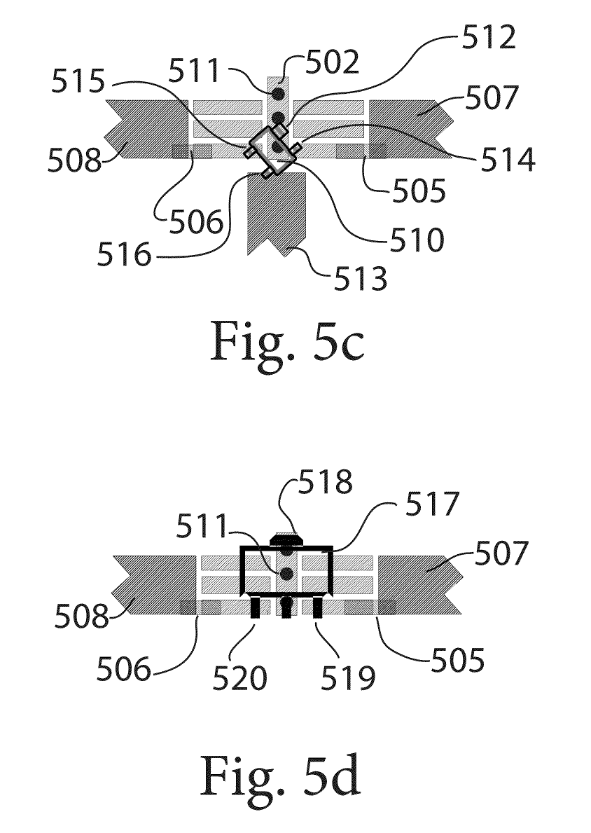

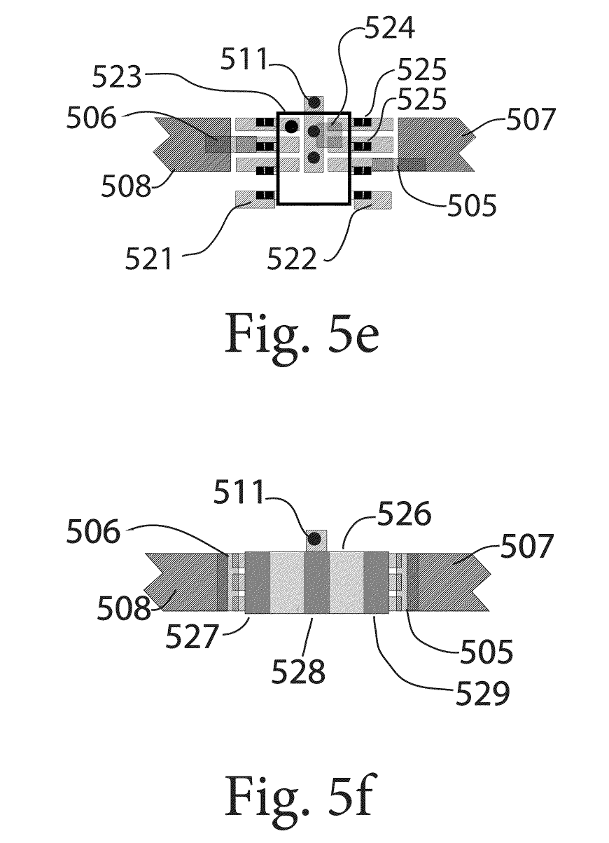

FIG. 5 shows several different components mounted using the boards from FIG. 3 and FIG. 4.

In FIG. 5a a Small Outline Transistor (SOT) 23-5 is shown. The main body 501 of the transistor overlaps the central pad 502; pad 502 is not electrically connected in this example. The plurality of leads from the transistor 503 connect to the plurality of pads 504. Bridging material 505 and 506 connects to the transmission line 507 and 508 respectively. The bridging material would typically be solder, but could also be a conductive ink or other conductive material.

In FIG. 5b a SOT-363 device 509 is mounted. Again the central pad 502 is not electrically used in this example, and the bridging material 505 and 506 is connecting two of the leads 503 to the transmission lines 507 and 508.

In FIG. 5c a SOT-343 device 510 is mounted, such as typically used in a mixer device. This example uses the central pad 502 shorted to the ground plane with via 511, which provides a low-impedance path to the ground lead 512 of the mixer part. Three transmission lines 507, 508, and 513 are connected to the parts leads 514, 515, and 516 respectively through use of solder and bridging material 505 and 506.

In FIG. 5d a SOT-89 device 517 is mounted, where the plurality of vias such as 511 provide a low-impedance path to ground for the device ground tab 518. The transmission lines 507 and 508 on the PCB are coupled to the device leads 519 and 520 via the bridging material 505 and 506.

In FIG. 5e additional pads 521 and 522 are added outside of the main footprint, demonstrating the extensions on which parts mount need not be directly in line with the main pad. A Small Outline Integrated Circuit (SOIC-8) package 523 is mounted, where leads of the device connect to the pads. Again the central pad is connected to the ground plane via a plurality of vias 511. This allows the bridging material 524 to form a low-impedance path to ground for the device grounding pins 525. The connection to transmission lines 507 and 508 is again made with a bridging material 505 and 506 such as solder.

In FIG. 5f a ceramic filter 526 is mounted. The ceramic filter has three connections: input 527, ground 528, and output 529. The plurality of vias 511 provides a low-impedance ground path. The bridging material 506 connections the transmission line 508 to the input, and bridging material 505 connects the output to transmission line 507.

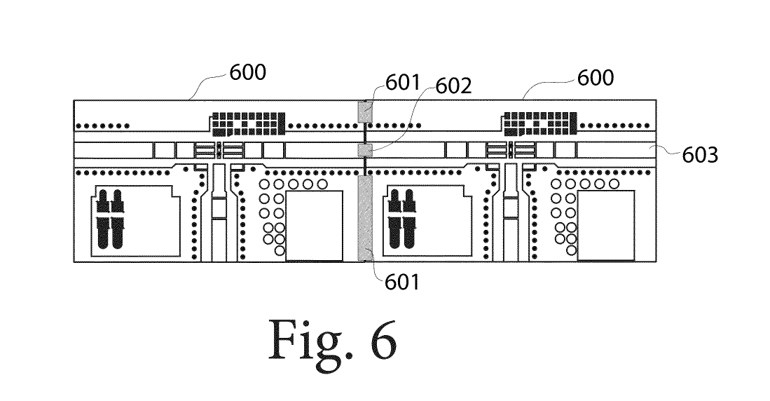

FIG. 6 shows an embodiment of the design, where several PCBs 600 are interconnected along the edge. Bridging material 601 is used to connect the ground planes of the PCBs along the edges, along with bridging material 602 connecting the planar transmission lines. The edges of the boards 603 are suitable for mounting end-launch connectors, such as SMA connectors for connecting the boards to additional systems.

I claim:

1. A footprint for generic circuit board layouts comprising:
a main mounting pad;
a plurality of extensions from this main pad which are electrically unconnected from this main pad, where the spacing and size of such extensions is designed to allow multiple dissimilar sized component packages to be mounted;
the design of the extensions is such that two or more of the extensions can be coupled to transmission lines using a bridging material;
the design of the pattern is such that it assumes a ground plane is present on a separate layer from the layer the pattern will be etched onto

2. The footprint of claim 1 wherein the bridging material is conductive ink

3. The footprint of claim 1 wherein the bridging material is solder

4. The footprint of claim 1 wherein the pattern is etched onto a printed circuit board, and positioned to allow the use of connectors as the transmission line

5. The footprint of claim 1 wherein the pattern of the mounting pad and extensions is positioned to allow the use of a microstrip as the transmission line

6. The footprint of claim 1 wherein the pattern of the mounting pad and extensions is positioned to allow the use of a co-planar line as the transmission line

7. The footprint of claim 1 wherein the pattern it is mounted to allow external connectors to form the transmission line

8. The footprint of claim 1 wherein the main pad is connected using a via to the ground plane

9. The footprint of claim 1 wherein the pattern of main pad and extensions allows coupling to a microscale device

10. The footprint of claim 1 wherein the pattern of main pad and extensions allows coupling to a small outline transistor package

11. The footprint of claim 1 wherein the pattern of main pad and extensions allows coupling to a small outline integrated circuit package

12. The footprint of claim 1 wherein the pattern of main pad and extensions allows coupling to a ceramic filter package

13. The footprint of claim 1 wherein it is mounted on a printed circuit board for use as platform to prototype high frequency systems

14. A printed circuit board designed for prototyping high frequency designs comprising:
one or more planar transmission lines etched into the top conductive layer, which have orthogonal slots cut into the transmission lines, where the slots can be bridged with a bridging material;
pads to allow mounting of connectors to couple signals to the transmission lines;
the planar transmission line(s) extend to the edge(s) of the circuit board, to allow the joining of printed circuit boards using a bridging material by abutting two such circuit boards together;
a ground plane on the bottom conductive layer which extends to one or more edges of the circuit board, to allow the bridging material to form a continuous ground plane between two circuit boards abutted together

15. The printed circuit board of claim 14 wherein the board has vias connecting portions of the etched top pattern to the bottom ground planes

16. The printed circuit board of claim 14 wherein the board uses an epoxy based substrate

17. The printed circuit board of claim 14 wherein the board has a non-conductive solder-mask on portions of the top or bottom layer

18. The printed circuit board of claim 14 wherein the board has a non-conductive legend on portions of the top or bottom layer
